(19) United States
(12) Patent Application Publication
(10) Pub. No.: US 2026/0198233 A1
(43) Pub. Date: Jul. 9, 2026

(54) METHOD FOR PRODUCING JOSEPHSON JUNCTIONS

(71) Applicant: COMMISSARIAT A L'ENERGIE ATOMIQUE ET AUX ENERGIES ALTERNATIVES, Paris (FR)

(72) Inventors: Thibaut CHENE, Grenoble cedex 09 (FR); Fabrice NEMOUCHI, Grenoble cedex 09 (FR); Francois LEFLOCH, Grenoble cedex 09 (FR); Roselyne SEGAUD, Grenoble cedex 09 (FR); Thierry CHEVOLLEAU, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/425,752

(22) Filed: Dec. 18, 2025

(30) Foreign Application Priority Data
Dec. 20, 2024 (FR) FR2414891

(51) Int. Cl. H10N 60/01; H10N 60/12; H10N 60/80; H10N 60/85

(52) U.S. Cl. CPC H10N 60/0912; H10N 60/12; H10N 60/805; H10N 60/855

(57) ABSTRACT

A method for manufacturing a Josephson junction, including a provision of a substrate, a formation of a first superconductor layer, a formation of a barrier layer, a structuration of the barrier layer to form a closed pattern and an open pattern, a formation of a second superconductor layer, an etching of the second superconductor layer, configured to form vias by stopping on the barrier layer, and an etching of the first superconductor layer on either side of the closed pattern and of the open pattern, configured to form lines.

### TECHNICAL FIELD

The present invention relates to the field of quantum electronics. It has a particularly advantageous application in the production of Josephson junctions integrated in back end of line levels of a microelectronic chip.

### PRIOR ART

The Josephson junction is presented in the form of two superconductors separated by a thin, insulating layer, which acts as a tunnel barrier between them. In a superconductor metal, the current circulates without dissipation, thanks to the “Cooper pairs”, which are pairs of paired electrons. When the barrier is sufficiently thin, it is possible to make the Cooper pairs pass through the barrier by quantum tunnel effect. Such a barrier letting the electrons pass between two superconductor regions is called a Josephson junction (JJ). This results in a non-dissipative current, the amplitude of which depends on the phase difference of the two superconductors.

A great variety of JJs exist, according to the nature of the barrier. The structure of the barriers can be based, non-exhaustively, on a non-superconductor insulating or metal materials, or on a geometric singularity or also on a grain boundary. The corresponding junctions can be of the “tunnel”, “construction” or “contact point” type, “any non-superconductor material” or also a grain junction.

Certain tunnel effect junctions typically have an SIS (superconductor-insulator-superconductor)-type structure; in these junctions, the transport mechanism is mainly dominated by the correlated tunnel effect of the electrons which form a Cooper pair through the insulating barrier. In an SNS (superconductor-normal metal-superconductor) junction, the transport mechanism is dominated mainly by the proximity effect. Generally, at the interface between a superconductor and a normal metal, the quantum coherence is also maintained in the normal metal under a distance defined by the phase coherence length.

The industrial manufacture of Josephson junctions in a superconductor integrated circuit is a major challenge for the development of quantum electronics.

Document EP3577700 proposes, for example, to use an SIS-type, trilayer construction integrated within different metal levels, typically in so-called “back end of line” or “BEOL” interconnecting levels. The SIS trilayer is, in this case, a Nb/Al—AlOx/Nb trilayer, with upper and lower superconductor layers comprising niobium, and an intermediate layer comprising superconductive aluminium also, and a thin aluminium oxide barrier layer.

This known solution requires a significant number of steps. The cost of the method is increased. There is therefore a need, aiming to optimise the method for producing JJs at least partially integrated in the “back end”.

An aim of the present invention is to respond to this need, by overcoming all or some of the disadvantages mentioned above.

In particular, an aim of the present invention is to propose a method for forming JJs integrated in interconnecting levels, which can be industrialised, and which has a reduced cost.

### SUMMARY

To achieve this aim, according to an embodiment, a method for manufacturing a Josephson junction is provided, comprising:
a provision of a substrate comprising at least one first connecting pad and a second connecting pad,
a formation of at least one first superconductor metal layer on exposed faces of the first and second connecting pads,
a formation, on the at least one first superconductor metal layer, of at least one etching stop layer,
a structuration of the at least one etching stop layer, through at least one first mask, so as to expose parts of the at least one first superconductor metal layer, and to preserve parts of the at least one etching stop layer in the form of at least one closed pattern surmounting the first connecting pad and at least one open pattern surmounting the second connecting pad, said at least one open pattern comprising at least one via opening, opening onto the at least one first underlying superconductor metal layer,
a formation of at least one second superconductor metal layer on the exposed parts of the at least one first superconductor metal layer and on the at least one closed pattern and the at least one open pattern,
a formation, on the at least one second superconductor metal layer, of at least one second mask defining at least one via level in vertical alignment with the at least one closed pattern and in vertical alignment with the at least one via opening of the at least one open pattern,
an etching of the at least one second superconductor metal layer, said etching being configured to form the vias of the at least one via level by stopping on the patterns of the at least one etching stop layer, and,
an etching of the at least one first superconductor metal layer on either side of the at least one closed pattern and of the at least one open pattern, said etching being configured to form lower level lines by stopping on the substrate.

Advantageously, the at least one closed pattern of the at least one etching stop layer comprises a barrier layer with the basis of a Josephson junction material having, opposite the at least one first superconductor metal layer, a selectivity S_{20a:30a} to the etching, greater than or equal to 10:1.

The vias of the second level surmounting the open patterns are connected to the lines of the first level through the at least one via opening. These lines of the first level are themselves connected to the pads of the substrate. Interconnections to the pads of the substrate are thus formed through several metal levels.

The vias of the second level surmounting the closed patterns are separated from the lines of the first level by the Josephson junction material. A Josephson junction is thus formed between several superconductor metal levels.

A quantum device comprising interconnections and at least one Josephson junction integrated in the “back end” is advantageously done. The formations of the interconnections and of the Josephson junction(s) are done advantageously during the same etching steps.

This method resorts to a barrier layer, structured and buried between the first and second superconductor metal layers. This barrier layer, which has a selectivity S_{21:30a} to the etching, greater than or equal to 10:1, advantageously acts as an etching stop layer. Such an etching stop interlayer advantageously makes it possible to successively perform the etching(s) of the superconductor metal layers, for example in one single step or in a sequenced manner. The number of steps of the method is thus limited.

The invention also provides, according to a second aspect, a device typically coming from this manufacturing method. This quantum device comprises, in a stack along a direction z:
a substrate comprising at least one first connecting pad and one second connecting pad,
an interconnection connecting the second connecting pad, comprising:
   at least one superconductor metal line with the basis of a first superconductor metal, and,
   at least one metal via with the basis of a second superconductor metal, connected to said at least one metal line,
   a barrier layer inserted between the at least one via and the at least one line, said barrier layer comprising at least one via opening, such that the at least one via and the at least one line are connected through said at least one via opening,
a Josephson junction connecting the first connecting pad, comprising:
   at least one metal line with the basis of the first semiconductor metal, and,
   at least one metal via with the basis of the second superconductor metal,
   a battery layer inserted between the at least one via and the at least one line, said barrier layer separating the at least one via and the at least one line.

The advantages described above regarding the method apply mutatis mutandis to the device according to the invention.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 12A schematically illustrate, in a cross-section, in a plane xz, different steps of the method for manufacturing a Josephson junction according to a first embodiment of the present invention.

FIGS. 1B to 12B schematically illustrate in perspective, the steps of the method for manufacturing a Josephson junction illustrated respectively in FIGS. 1A to 12A, according to the first embodiment of the present invention.

FIGS. 13A, 13B schematically illustrate a device comprising several JJs in parallel according to an embodiment of the present invention.

FIGS. 14A to 18A schematically illustrate, in a cross-section, in a plane xz, different steps of the method for manufacturing a Josephson junction according to a second embodiment of the present invention.

FIGS. 14B to 18B schematically illustrate in perspective, the steps of the method for manufacturing a Josephson junction illustrated respectively in FIGS. 14A to 18A, according to the second embodiment of the present invention.

The drawings are given as examples and are not limiting of the invention. They constitute principle schematic representations, intended to facilitate the understanding of the invention, and are not necessarily to the scale of practical applications. In particular, the thicknesses and/or the dimensions of the different layers and patterns are not representative of reality.

### DETAILED DESCRIPTION

Before starting a detailed review of embodiments of the invention, optional features are stated below, which can optionally be used in association or alternatively:
According to an example, the at least one etching stop layer has, with respect to the at least one first superconductor metal layer, a selectivity S_{20a:30} to the etching, greater than or equal to 10:1.

According to an example, the barrier layer has a thickness e₃₀ₐ of between 1 nm and nm, and preferably between 1 nm and 5 nm.

According to an example, the barrier layer has a selectivity to the etching S_{21:32a} or S_{21:31}, greater than or equal to 10:1 with respect to the first superconductor metal.

According to an example, the barrier layer is with the basis of a material taken from among: MgO, SiO₂, AlOₓ, TiO₂.

According to an example, the barrier layer inserted between the at least one via and the at least one line of the Josephson junction is continuous and does not comprise any via opening.

According to an example, the structuration of the barrier layer comprises the following substeps:
a formation of the first mask on the barrier layer, said first mask directly defining the at least one closed pattern and the at least one open pattern comprising the at least one via opening,
a partial removal of the barrier layer, only at the zones of the barrier layer not covered by the first mask, so as to expose the first superconductor metal layer outside of the zones covered by the first mask,
a removal of the first mask.

In this example, the parts covered by the first mask correspond to the open and closed patterns. The lower part of the Josephson junction and the lines of the first level contributing to the interconnections are defined, thanks to the single first mask.

According to an example, the formation of the first mask is done by double lithography. This known lithography method makes it possible to optimise, even exceed the resolution limitations of a piece of conventional lithography insolation equipment. Another solution consists of using a piece of better resolved lithography equipment, for example, in extreme UV or in electronic lithography. The formation of the first mask can comprise a first lithography, followed by a second lithography, then an etching. Alternatively, the formation of the first mask can comprise a first lithography followed by a first etching, then a second lithography followed by a second etching.

According to an example, the via(s) of the at least one via level surmounting the closed pattern(s) have a critical dimension CDᵥᵢₐ₂₂₁, taken along an axis x, less than a dimension CD₁, taken along the axis x, of the closed pattern(s). This makes it possible to minimise the risk linked to a misalignment between the first and second masks. The lines of the first level, typically being wider than the vias of the second level, the etching of the second superconductor metal layer, associated with the formation of the vias of the second level, will actually stop on the barrier layer, structured along the closed pattern(s). The reliability of the method is increased.

According to an example, the via(s) of the at least one via level surmounting the open pattern(s) have a critical dimension CDᵥᵢₐ₂₂₂, taken along an axis x, greater than or equal to a dimension CDₒₚₑₙ of the at least one via opening taken along the axis x. This makes it possible to minimise the risk linked to a misalignment between the first and second masks. The vias of the at least one via level, typically being wider than the via openings, the alignment of the second mask defining the vias in vertical alignment with the via openings is facilitated. The etching of the second superconductor metal layer, during the formation of the vias of the at least one via level, will actually stop on the etching stop layer or on the barrier layer, structured along the open pattern(s). The etching of the second superconductor metal layer does not extend to the via openings. The reliability of the method is increased.

According to an example, the first and second superconductor metal layers are with the basis of one same superconductor metal material, for example, ZrN, HfN, W, Nb, NbN, Ta, TaN, Ti, TiN, Al and their alloys.

According to an example, the etching of the second superconductor metal layer and the etching of the first superconductor metal layer are done by one single and same etching, during one single and same step.

According to an example, the first and second superconductor metal layers are respectively with the basis of a first superconductor metal material and of a second superconductor metal material, said first and second superconductor metal materials being different from one another.

According to an example, the etching of the second superconductor metal layer and the etching of the first superconductor metal layer are done by two different successive etchings.

According to an example, the at least one closed pattern comprises a first closed pattern and a second closed pattern, said closed patterns being surmounted respectively by third and fourth vias. According to an example, the method further comprises, after formation of the assembly of the vias of the at least one via level and of the assembly of the lower level lines, a formation of at least one upper level superconductor metal line connecting the third and fourth vias, so as to form a device comprising several Josephson junctions. According to a principle of the invention, several “vertical” Josephson junctions can be formed side-to-side, between superconductor interconnections. It is thus possible to connect two adjacent Josephson junctions.

According to an example, a method for manufacturing a Josephson junction is provided, comprising:
a provision of a substrate comprising at least one first connecting pad and one second connecting pad,
a formation of a first superconductor metal layer on exposed faces of the first and second connecting pads,
a formation, on the first superconductor metal layer, of a barrier layer with the basis of a Josephson junction material having, with respect to the first superconductor metal layer, a selectivity S_{21:30a} to the etching, greater than or equal to 10:1,
a structuration of the barrier layer, through at least one first mask, so as to expose parts of the first superconductor metal layer, and to preserve parts of the barrier layer in the form of at least one closed pattern surmounting the first connecting pad and at least one open pattern surmounting the second connecting pad, said at least one open pattern comprising at least one via opening, opening onto the first underlying superconductor metal layer,
a formation of a second superconductor metal layer on the exposed parts of the first superconductor metal layer and on the at least one closed pattern and the at least one open pattern,
a formation, on the second superconductor metal layer, of a second mask defining a second via level in vertical alignment with the at least one closed pattern and in vertical alignment with the at least one via opening of the at least one open pattern,
an etching of the second superconductor metal layer, said etching being configured to form the vias of the second level by stopping on the barrier layer, and,
an etching of the first superconductor metal layer on either side of the at least one closed pattern and the at least one open pattern, said etching being configured to form first level lines by stopping on the substrate.

In this example, the barrier layer is advantageously used as a barrier layer for the Josephson junction and as an etching stop layer for the production of lines and of interconnecting vias. One single and same layer is used to fulfil the barrier functions in the Josephson junction and etching stop in the structuration of the superconductor metal levels of the interconnections. The number of steps of the method is significantly reduced. The cost of the method is decreased.

According to an example, the first superconductor metal layer and/or the second superconductor metal layer are presented in the form of stacks comprising several superconductor materials, for example, in the form of multilayers. This makes it possible, for example, to benefit from the qualities or the properties of each of these materials. A high critical temperature, due to a first superconductor material, can thus be obtained by proximity effect in a second superconductor material used for the interface quality that it forms with the barrier layer.

According to an example, a method for manufacturing a Josephson junction is provided, comprising:
a provision of a substrate comprising at least one first connecting pad and a second connecting pad,
a formation of a first superconductor metal layer on exposed faces of the first and second connecting pads,
a formation, on the first superconductor metal layer, of an etching stop layer having, with respect to the first superconductor metal layer, a selectivity S_{21:30b} to the etching, greater than or equal to 10:1,
a structuration of the etching stop layer, through at least one first mask, so as to expose parts of the first superconductor metal layer and to preserve parts of the etching stop layer in the form of at least one open pattern surmounting the first and second connecting pads, said at least one open pattern comprising at least one via opening, opening onto the first underlying superconductor metal layer,
a formation of a second superconductor metal layer on the exposed parts of the first superconductor metal layer and on the at least one open pattern,
a formation, on the second superconductor metal layer, of a barrier layer with the basis of a Josephson junction material having, with respect to the second superconductor metal layer, a selectivity S_{22:30a} to the etching, greater than or equal to 10:1,
a structuration of the barrier layer, through at least one second mask, so as to expose parts of the second superconductor metal layer and to preserve parts of the barrier layer in the form of at least one closed pattern surmounting the first connecting pad,
a formation of a third superconductor metal layer on the exposed parts of the second superconductor metal layer and on the at least one closed pattern,
a formation, on the third superconductor metal layer, of a third mask defining vias in vertical alignment with the at least one closed pattern and in vertical alignment with the at least one via opening of the at least one open pattern,
at least one etching of the third, second and first superconductor metal layers, said at least one etching being configured to form the vias by stopping on the barrier layer and on the etching stop layer, and to form first level lines by stopping on the substrate.

In this example, the lower part of the Josephson junction is formed from first and second superconductor metal layers. The lines of the first level contributing to the interconnections are formed from the first superconductor metal layer.

In this example, the Josephson junction is formed within the upper interconnecting levels. The barrier layer only forms the closed pattern. The underlying etching stop layer forms an open pattern. This makes it possible to consider different combinations of closed and open patterns. The sizing of the lower part of the Josephson junction and/or of the barrier layer of the Josephson junction is better controlled. The etching selectivity between the different superconductor metal layers and the barrier layer can be adjusted, for example, reduced.

According to an example, the at least one closed pattern has a dimension CD₁, taken along an axis, less than a dimension CD₂, taken along the axis x, of the at least one underlying open pattern.

According to an example, the at least one metal via of the interconnection connecting the second connecting pad has a critical dimension CDᵥᵢₐ₂₂₂, taken along an axis x, greater than or equal to a dimension CDₒₚₑₙ of the at least one via opening taken along the axis x.

According to an example, the at least one metal via of the Josephson junction has a critical dimension CDᵥᵢₐ₂₂₁, taken along an axis x, strictly less than a dimension CD₃₁, taken along the axis x, of the barrier layer separating the at least one via and the at least one line of the Josephson junction.

According to an example, the first and second superconductor metals are with the basis of the same metal taken from among ZrN, HfN, W, Nb, NbN, Ta, TaN, Ti, TiN, Al and their alloys.

According to an example, the at least one superconductor metal line of the interconnection is connected to the second connecting pad. According to an example, the at least one superconductor metal line of the Josephson junction is connected to the first connecting pad.

Unless incompatible, it is understood that all of the optional features above and/or the variants indicated can be combined, so as to form an embodiment which is not necessarily illustrated or described. Such an embodiment is clearly not excluded from the invention.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer covers, at least partially, the second layer, by being either directly in contact with it, or by being separated from it by at least one other layer or at least one other element.

By a substrate, a film, a layer “with the basis” of a material A, this means a substrate, a film, a layer comprising this material A only, or this material A and optionally other materials, for example, doping elements or alloy elements. Thus, a silicon nitride SiN-based etching stop layer can, for example, comprise non-stoichiometric silicon nitride (SiN), or stoichiometric silicon nitride (Si₃N₄), or also a silicon oxynitride (SiON).

By closed pattern, this means a pattern which does not communicate with the underlying layer. On the contrary, by open pattern, this means a pattern which communicates with the underlying layer through an opening, typically through a via opening.

In the scope of the present invention, a barrier can be seen as a structural description and a junction can be seen as a functional description of the same entity. A barrier means a barrier formed of a non-superconductor material. A “Josephson junction material” can be a dielectric material or a non-superconductor metal.

The productions of Josephson junctions considered in the present invention are particularly adapted to the field of Josephson Tunnel Junctions. Other fields of application can be fully considered.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method. The etchings of the first and second metal layers can, in particular, be sequenced or be considered as forming part of one single and same etching step.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures.

In the present patent application, preferably thickness will be referred to for a layer or a film, and height will be referred to for a device or a structure. The thickness is taken along a direction normal to the main extension plane of the layer or of the film. Thus, a metal layer typically has a thickness along z. A via formed from such a metal layer has a height along z. The relative terms “on”, “surmounts”, “upper”, “under”, “underlying”, “lower” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another elements, means that these two elements are both located on one same line perpendicular to a plane into which a lower or upper face of a substrate mainly extends, i.e. on one same line oriented vertically in the figures as a cross-section.

The terms “substantially”, “around”, “about” mean plus or minus 10%, and preferably plus or minus 5%. Moreover, the terms “between . . . and . . . ” and equivalents mean that the limits are inclusive, unless mentioned otherwise.

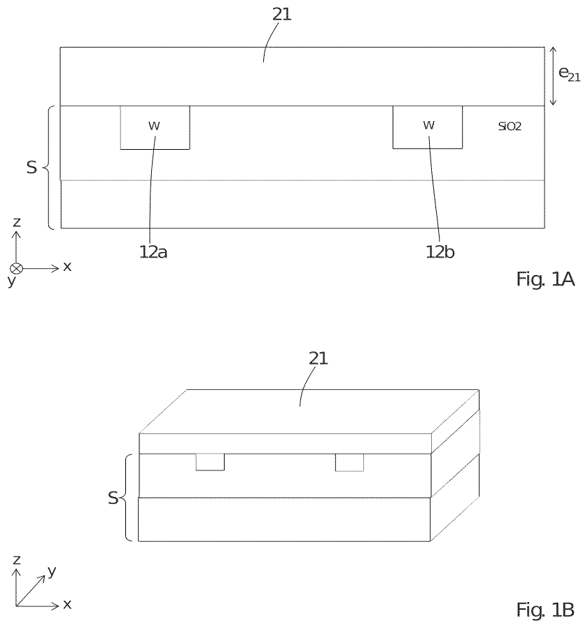

Steps of manufacturing a device comprising a Josephson junction (JJ) integrated in an interconnecting level are illustrated in FIGS. 1A, 1B to 12A, 12B, according to a first embodiment of the invention.

As illustrated in FIGS. 1A, 1B, the method comprises a provision of a substrate S, for example, silicon-based, comprising connecting pads 12a, 12b. The connecting pads 12a, 12b can correspond to a MEOL (middle end of line)-type intermediate interconnecting lines.

A first superconductor metal layer 21, typically with the basis of a metal taken from among ZrN, HfN, W, Nb, NbN, Ta, TaN, Ti, TiN, Al and their alloys, is first formed on this substrate S. This superconductor metal layer 21 is directly in contact with the connecting pads 12a, 12b. This superconductor metal layer 21 typically has a thickness e₂₁ of around a few tens of nanometres to a few hundreds of nanometres, for example, between 40 nm and 200 nm. The deposition of this superconductor metal layer 21 can, in particular, be done by one of the following techniques: physical vapour deposition (PVD), chemical vapour deposition (CVD), atomic layer deposition (ALD). After deposition, the first superconductor metal layer 21 can be planarised, for example, by chemical-mechanical polishing CMP. The first superconductor metal layer 21 typically corresponds to a first superconductor metal level.

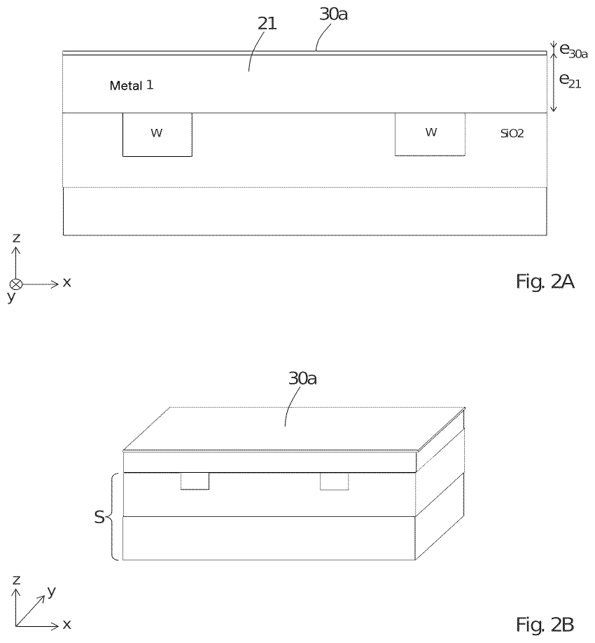

As illustrated in FIGS. 2A, 2B, a barrier layer 30a is then directly formed on the first superconductor metal layer 21. This barrier layer 30a typically has a thickness e₃₀ₐ of around a few nanometres, for example, between 5 nm and 15 nm. It is with the basis of a non-superconductor “Josephson junction” material, for example, with the basis of a material taken from among: MgO, SiO₂, AlOₓ, TiO₂. The deposition of this barrier layer 30a can, in particular, be done by one of the following techniques: physical vapour deposition (PVD), chemical vapour deposition (CVD), plasma enhanced chemical vapour deposition (PECVD), atomic layer deposition (ALD), plasma enhanced atomic layer deposition (PEALD).

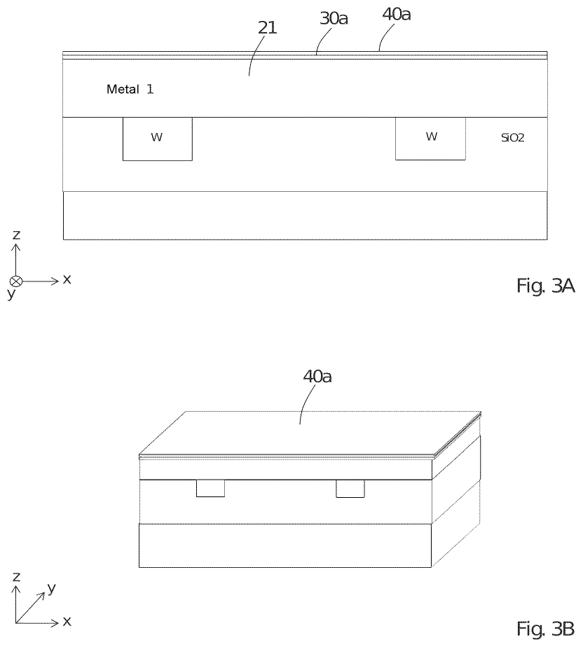

As illustrated in FIGS. 3A, 3B, optionally only, a protective layer 40a can be deposited on the barrier layer 30a, to preserve said barrier layer 30a of the oxidation.

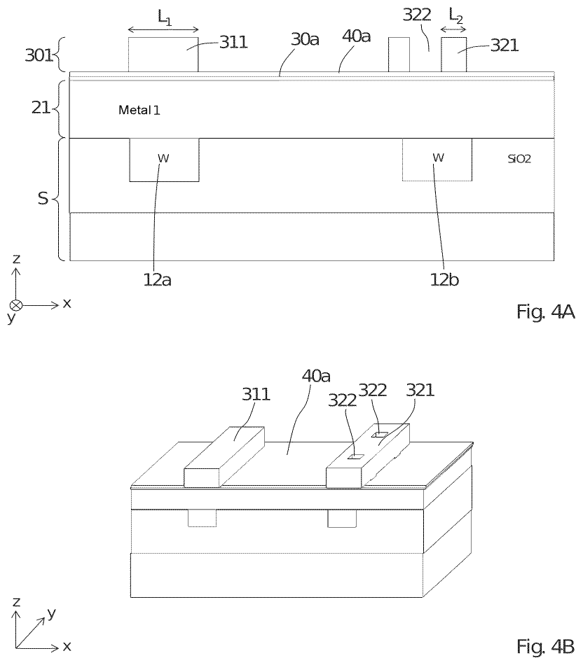

As illustrated in FIGS. 4A, 4B, an etching mask 301 is formed on the barrier layer 30a. This etching mask 301 is, for example, SiON-based, for example, in the form of a stack known as a “trilayer”, typically comprising an organic planarisation layer, an antireflection layer and a photosensitive resin layer. It is typically obtained by lithography/etching, for example, through a simple lithography in extreme UV insolation, or through a double lithography, also called “double patterning”.

The etching mask 301 comprises a solid pattern 311 above the connecting pad 12a, and an open pattern 321 above the connecting pad 12b. The open pattern 321 comprises one or more openings 322, opening onto the underlying layer, for example, protective layer 40a as illustrated in this case, or directly on the barrier layer 30a. The solid pattern 311 typically has a dimension L₁ along x of between 20 nm and 300 nm, preferably between 20 nm and 150 nm, according to the lithography technique implemented. The open pattern 321 typically has a dimension L₂ along x of between 8 nm and 150 nm, preferably between 8 nm and 50 nm, according to the lithography technique implemented.

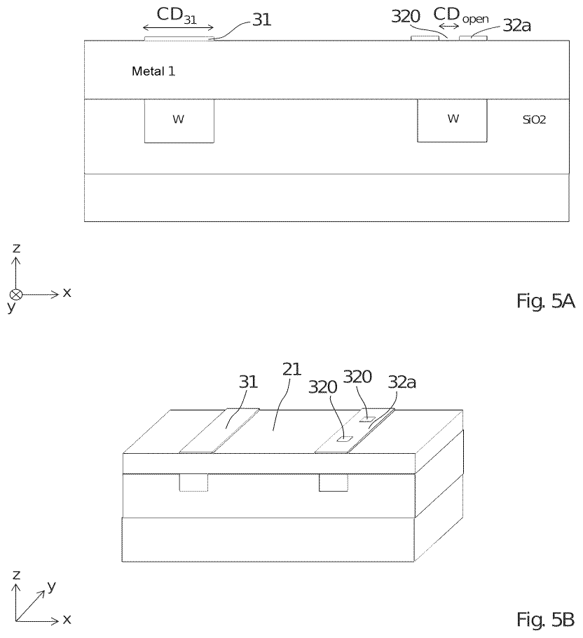

As illustrated in FIGS. 5A, 5B, the patterns 311, 321 are transferred into the barrier layer 30a by anisotropic etching along z of the barrier layer 30a in the presence of the mask 301. The etching of the barrier layer 30a can be done by plasma with the basis of a halogenated etching chemistry, for example, with the basis of a chlorinated chemistry.

Alternatively, the etching of the “Josephson junction” material can be done in fluorinated or fluorocarbon chemistry. In this case, it is preferable to avoid SiN and SiO₂ as a Josephson junction material. The solid pattern 311 of the mask 301 forms after etching the closed pattern 31 in the barrier layer 30a. The open pattern 321 of the mask 301 forms after etching the open pattern 32a comprising the via openings 320 in the barrier layer 30a. The patterns 31, 32a have substantially the same dimensions as the patterns 311, 321. The closed pattern 31 typically has the dimension CD₃₁ along x, and the via openings 320 of the open pattern 32a typically have the dimension CDₒₚₑₙ along x. The dimension CDₒₚₑₙ along x can be between 10 nm and 100 nm, preferably between 10 nm and 50 nm, according to the lithography technique implemented. The mask 301 is removed after etching, for example, by oxygen-based plasma. The protective layer 40a is also removed, if necessary, for example, by NF₃ or NH₃ plasma in-situ, so as to expose the patterns 31, 32a of the barrier layer 30a.

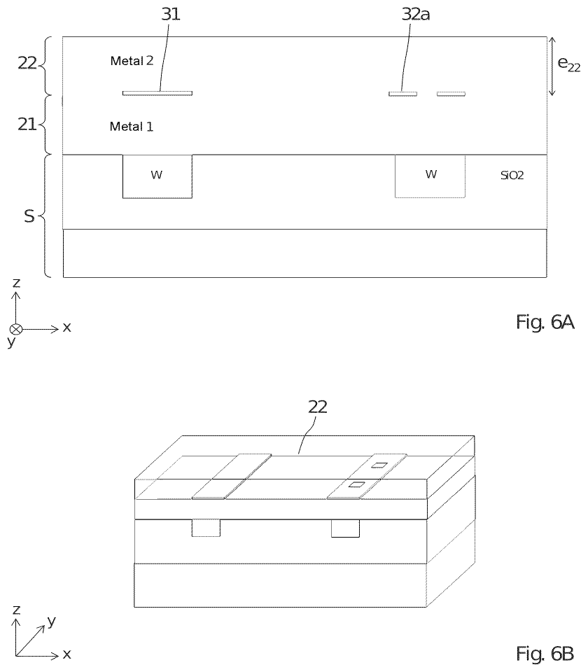

As illustrated in FIGS. 6A, 6B, after structuration of the barrier layer 30a, a second superconductor metal layer 22, typically with the basis of a metal taken from among ZrN, HfN, W, Nb, NbN, Ta, TaN, Ti, TiN, Al and their alloys, is then formed on the first superconductor metal layer 21, and on the closed pattern 31 and the open pattern 32a. This superconductor metal layer 22 typically has a thickness e₂₂ of around a few tens of nanometres to a few hundreds of nanometres, for example, between 40 nm and 200 nm. The deposition of this metal layer 22 can, in particular, be done by PVD, CVD, PECVD, ALD or PEALD. After deposition, the second superconductor metal layer 22 can be planarised, for example, by CMP. The second superconductor metal layer 22 typically corresponds to a second superconductor metal level.

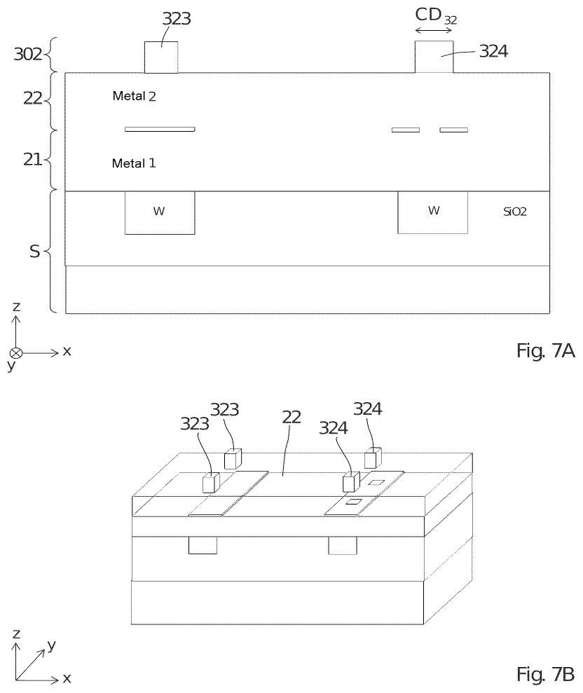

As illustrated in FIGS. 7A, 7B, a second etching mask 302 comprising via patterns 323, 324 is formed on the second superconductor metal layer 22. This second etching mask 302 is preferably organic layer-based, for example, in the form of a “trilayer” stack, typically comprising an organic planarisation layer, an antireflection layer and a photosensitive resin layer.

The via patterns 324 of this second etching mask 302 are aligned in vertical alignment with the via openings 320 of the open pattern 32a. The via patterns 323 of this second etching mask 302 are aligned in vertical alignment with the closed pattern 31. The via patterns 324 typically have a dimension CD₃₂ along x slightly greater, for example, 10% greater, than the dimension CDₒₚₑₙ along x of the via openings 320 of the open pattern 32a. This facilitates the alignment of the patterns 324, 32a to one another. A certain tolerance on the alignment accuracy is thus obtained. The dimension CD₃₂ along x of the via patterns 324 is, for example between 10 nm and 150 nm.

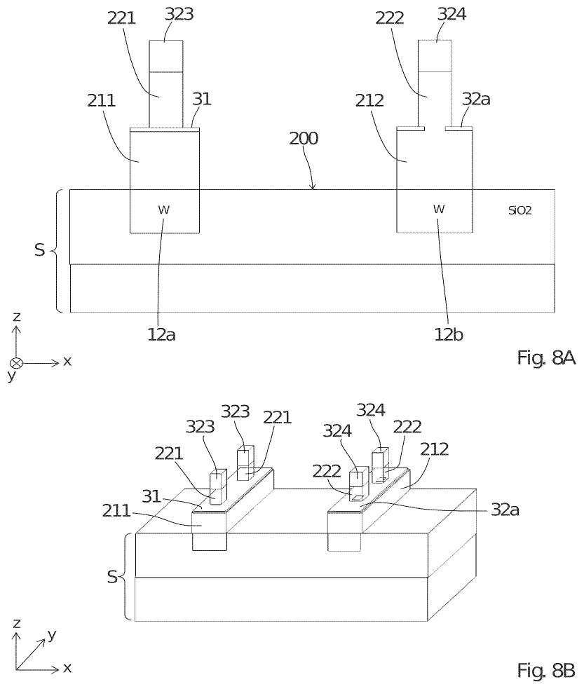

As illustrated in FIGS. 8A, 8B, the first and second superconductor metal layers 21, 22 are then etched over the entire thickness, along z, on either side of the via patterns 323, 324 and on either side of the open pattern 32a and of the closed pattern 31. The second superconductor metal layer 22 is first etched to form the vias 222, 221, then the first superconductor metal layer 21 is etched to form the lines 212, 211. The etchings of the first and second superconductor metal layers 21, 22 are preferably sequenced. According to an option, in particular, when the first and second superconductor metal layers 21, 22 are of an identical nature, the etchings of these superconductor metal layers 21, 22 are done in one single and same step, with the same etching chemistry.

The etchings are, in this case, chosen so as to selectively etch the first and second metals of the first and second superconductor metal layers 21, 22 with respect to the material of the barrier layer (structured in the form of patterns 31, 32a). The barrier layer is, in this case, advantageously used as an etching stop layer. In particular, the etching selectivity S_{21:30a}, i.e. the ratio between the etching speed of the metal of the first superconductor metal layer 21 over the etching speed of the material of the barrier layer, is greater than or equal to 10:1, preferably greater than or equal to 10:1. The etchings can be with the basis of a fluorinated chemistry.

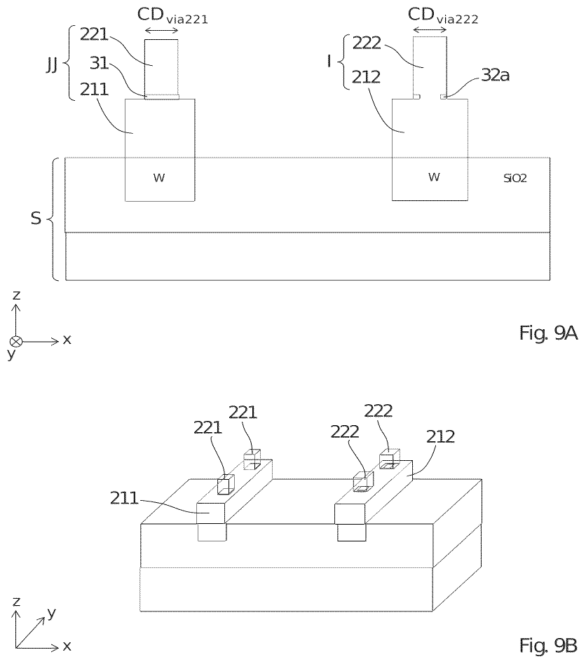

As illustrated in FIGS. 9A, 9B, after etching, the mask 302 is removed, for example, by oxygen-based plasma. Vias 222 having the dimension CDᵥᵢₐ₂₂₂ along x are obtained above the openings of the open pattern 32a. The dimension CDᵥᵢₐ₂₂₂ is substantially equal to the dimension CD₃₂ of the via patterns 324. Vias 221 having the dimension CDᵥᵢₐ₂₂₁ along x are obtained above the closed pattern 31. A quantum device comprising interconnections I (212, 222) and one or more Josephson junctions JJ (211, 31, 221) integrated in the interconnecting levels is thus advantageously obtained. The Josephson junctions JJ comprise, in this case, a lower part formed by the line 211, an upper part formed by the via 221, and a barrier 31 between the lower and upper parts. The Josephson junctions JJ are, in this case, integrated between the first and second superconductor metal levels.

In the example illustrated in FIGS. 9A, 9B, according to an only optional option, an anisotropic etching along z is done to partially remove the barrier layer, on either side of the vias 221, 222. The lines 211, 212 have, in this case, partially exposed horizontal surfaces.

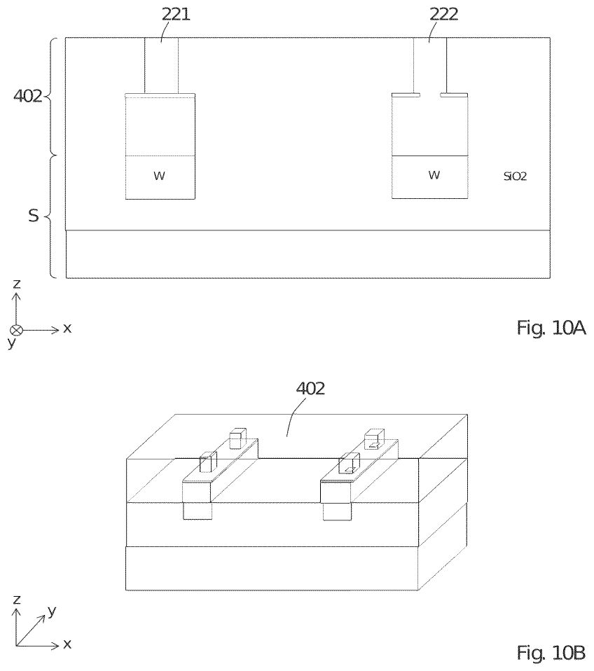

As illustrated in FIGS. 10A, 10B, the interconnections I and the Josephson junctions JJ are then conventionally integrated in a dielectric matrix by deposition and planarisation of a dielectric layer 402, typically SiO₂-based.

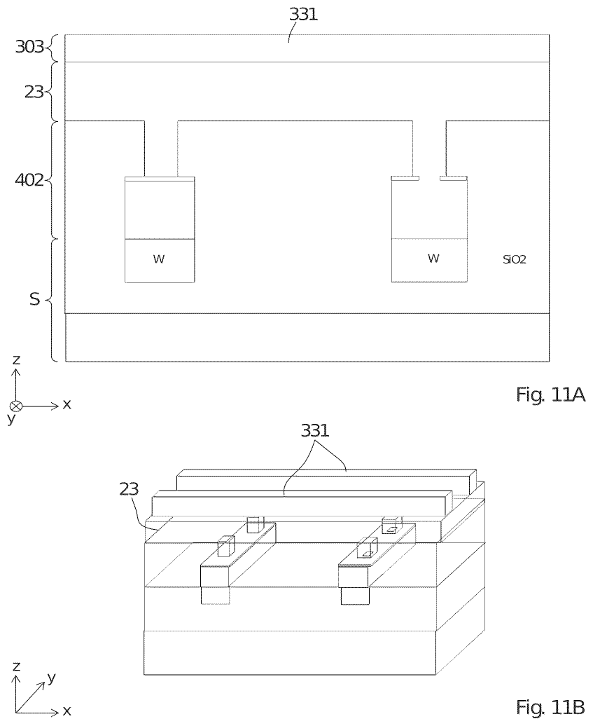

As illustrated in FIGS. 11A, 111B, a third superconductor metal layer 23, for example, ZrN-, HfN-, W-, Nb-, NbN-, Ta-, TaN-, Ti-, TiN-, Al-based and their alloys, corresponding to a third superconductor metal level, can then be deposited on the layer 402 and the vias 221, 222 are flush. A third mask 303 comprising, for example, line patterns 331 can be formed on this third superconductor metal layer 23.

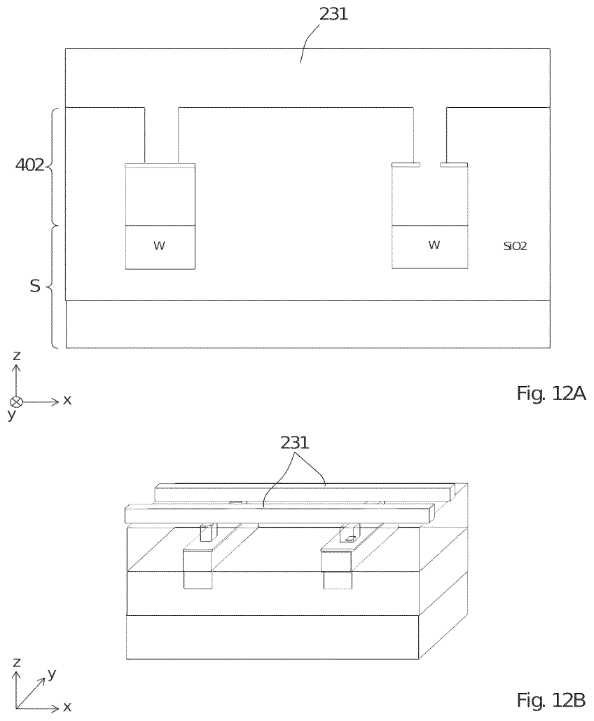

As illustrated in FIGS. 12A, 12B, the third superconductor metal layer 23 is then structured by etching through the mask 303. Lines 231 are thus formed in the third superconductor metal level. These lines 231 typically connect the vias 221, 222 of the second superconductor metal level.

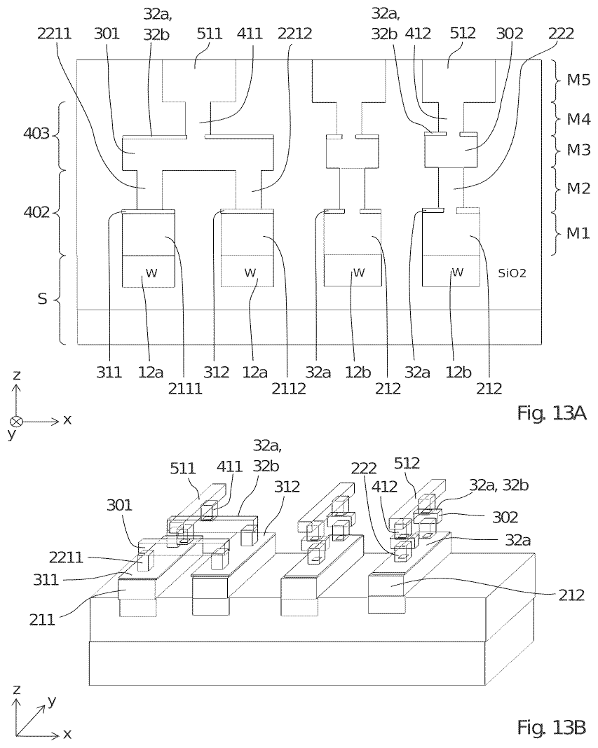

FIGS. 13A, 13B illustrate a quantum device obtained by the method according to the invention, comprising Josephson junctions connected in series in pairs. In this example, the Josephson junctions are integrated between the first and second superconductor metal levels M1, M2. A first Josephson junction is formed by a first line 2111, a first barrier 311 and a first via 2211. A second Josephson junction is formed by a second line 2112, a second barrier 312 and a second via 2212. The first and second Josephson junctions are preferably located side-by-side. The first and second vias 2211, 2212 are, in this case, connected to one another by a superconductor line 301 formed in the third superconductor metal level.

The superconductor line(s) 301 can be formed as above, by using a barrier layer structured in the form of open patterns 32a, or alternatively by using an etching stop layer structured in the form of open patterns 32b. Vias 411 connected to the superconductor lines 301 through openings of the open patterns 32a, 32b, and lines 511 can then be formed, for example, conventionally, by a known “damascene”- or “double damascene”-type technique. The corresponding metal levels can be superconductive or simply metal.

As above, interconnections can be formed in the metal levels M1, M2, M3, M4, M5, at the same time as the first and second Josephson junctions. These interconnections typically comprise a succession of vias and of lines with inserted open patterns 32a, 32b. In particular, an interconnection surmounting a pad 12b comprises, in this case, a line 212, a via 222 connected to the line 212 through an open pattern 32a, a pad or a line 302, a via 412 connected to the line 302 through an open pattern 32a, 32b, a line 512.

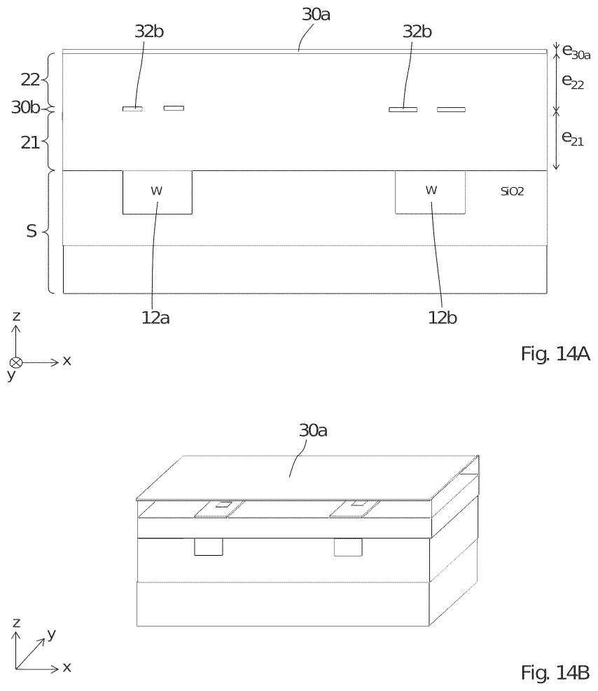

FIGS. 14A, 14B to 18A, 18B illustrate steps of manufacturing a device comprising one or more integrated Josephson junctions (JJ), according to a second embodiment of the invention. In this second embodiment, the Josephson junctions of the device are integrated in upper interconnecting levels. Only the different steps and features of the first embodiment are detailed below, the other steps and features being considered identical to those of the first embodiment.

As illustrated in FIGS. 14A, 14B, after formation of the first superconductor metal layer 21, an etching stop layer 30b is formed on the first superconductor metal layer 21, then structured in the form of open patterns 32b only, above the connecting pads 12a, 12b. This etching stop layer is preferably with the basis of a dielectric material, taken from among: SiO₂, TiO₂, HfO₂, MgO. A second superconductor metal layer 22, is then formed as above, on the first superconductor metal layer 21, and on the open patterns 32b.

A barrier layer 30a, different or distinct from the etching stop layer 30b, is, in this case, formed on the second superconductor metal layer 22. As above, this barrier layer 30a typically has a thickness e₃₀ₐ of around a few nanometres, for example, between 1 nm and nm. It is preferably with the basis of material taken from among: SiO₂, AlOₓ, TiO₂, MgO.

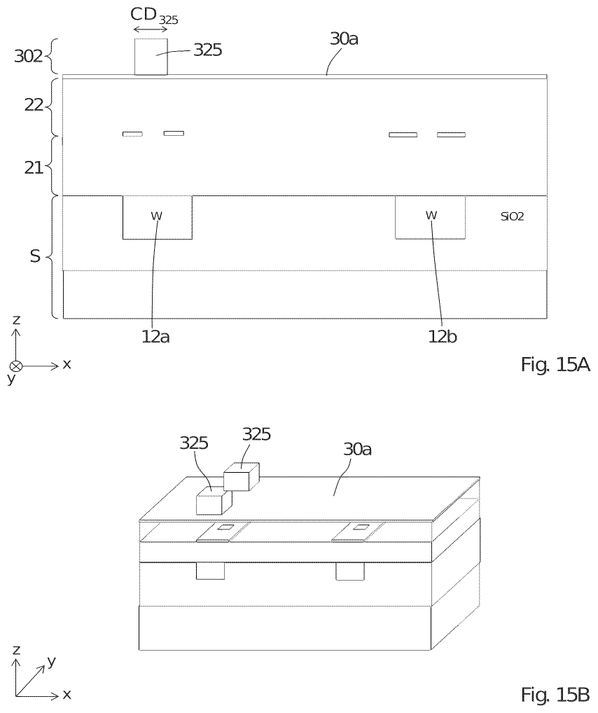

As illustrated in FIGS. 15A, 15B, a second etching mask 302 comprising intermediate patterns 325 is formed on the barrier layer 30a. These intermediate patterns 325 are aligned in vertical alignment with the via openings 320 of the open pattern 32b located above the pad 12a, in the example illustrated. These intermediate patterns 325 typically have a dimension CD₃₂₅ along x greater, for example, at least 20% greater, than the dimension CDₒₚₑₙ along x of the via openings 320 of the open pattern 32b. This facilitates the alignment of the patterns 325, 32b together. The sizing of the lower part of the Josephson junctions is also better controlled. The dimension CD₃₂₅ along x of the intermediate patterns 325 is, for example, between 10 nm and 200 nm.

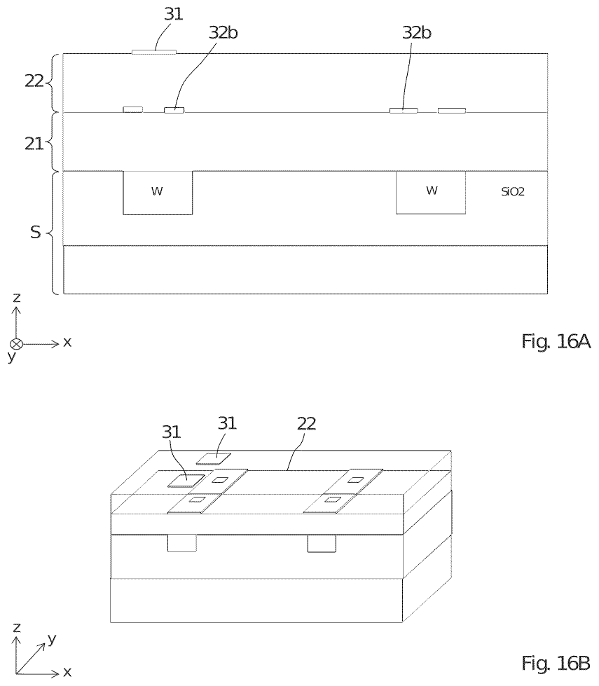

As illustrated in FIGS. 16A, 16B, the patterns 325 are transferred into the barrier layer 30a by anisotropic etching along z of the barrier layer 30a in the presence of the mask 302. The patterns 325 of the mask 302 form, after etching, the closed patterns 31 in the barrier layer 30a. The mask 302 is removed after etching, for example, by oxygen-based plasma.

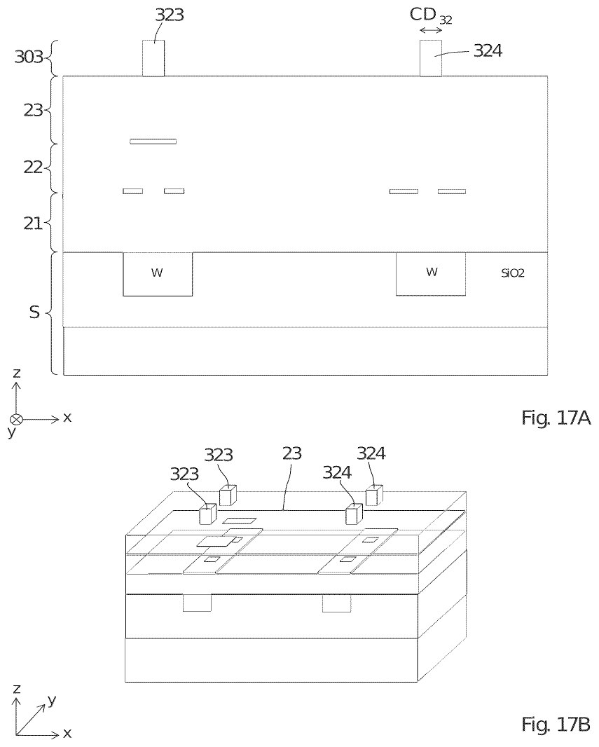

As illustrated in FIGS. 17A, 17B, after structuration of the barrier layer 30a, a third superconductor metal layer 23, typically with the basis of a metal taken from among ZrN, HfN, W, Nb, NbN, Ta, TaN, Ti, TiN, Al and their alloys, is then formed on the second superconductor metal layer 22, and on the closed patterns 31. The third superconductor metal layer 23 typically corresponds to a third superconductor metal level.

A third etching mask 303 comprising via patterns 323, 324 is formed on the third superconductor metal layer 23. The via patterns 324 of this third etching mask 303 are aligned in vertical alignment with the via openings 320 of the open pattern 32b. The via patterns 323 of this third etching mask 303 are aligned in vertical alignment with the closed patterns 31. The via patterns 324 typically have a dimension CD₃₂ along x, slightly greater, for example, 10% greater, than the dimension CDₒₚₑₙ along x of the via openings 320 of the open pattern 32b. This facilitates the alignment of the patterns 324, 32b together. The dimension CD₃₂ along x of the via patterns 324 is, for example, between 10 nm and 150 nm.

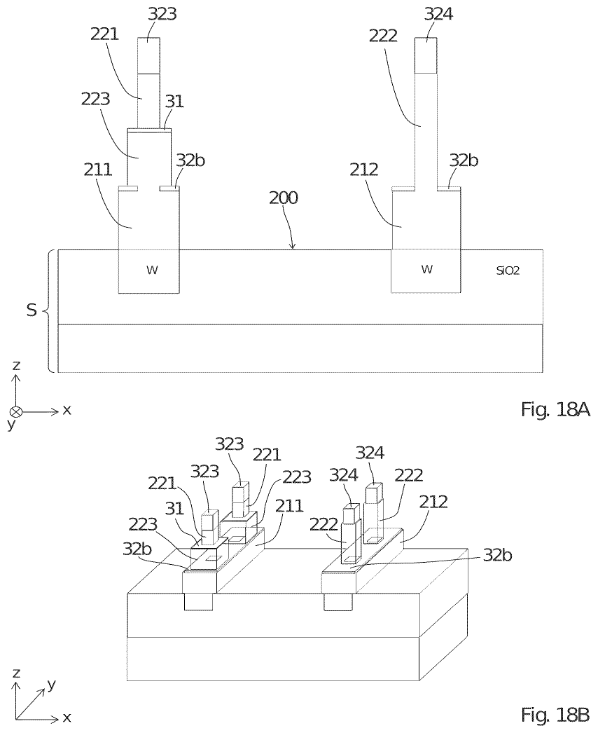

As illustrated in FIGS. 18A, 18B, the first, second and third superconductor metal layers 21, 22, 23 are then etched over their entire thickness, along z, on either side of the via patterns 323, 324, and on either side of the open patterns 32b and of the closed pattern 31. The third and second superconductor metal layers 23, 22 are first etched to form the vias 222, 221 and the pad 223, then the first superconductor metal layer 21 is etched to form the lines 212, 211. The etchings of the first, second and third superconductor metal layers 21, 22, 23 are preferably sequenced. According to an option, in particular, when the first, second and third superconductor metal layers 21, 22, 23 are of an identical nature, the etchings of these superconductor metal layers 21, 22, 23 are done in one single and same step, with the same etching chemistry.

The etchings are, in this case, chosen so as to selectively etch the metals of the first, second and third superconductor metal layers 21, 22, 23 with respect to the material of the barrier layer, structured in the form of the pattern 31) and with respect to the material of the etching stop layer (structured in the form of patterns 32b). The etching stop layer and the barrier layer are used as etching stop layers. In particular, the etching selectivity S_{22:31}, i.e. the ratio between the etching speed of the metal of the second superconductor metal layer 22 over the etching speed of the material of the barrier layer, is greater than or equal to 10:1, preferably greater than or equal to 10:1, preferably greater than or equal to 10:1. The etching selectivity S_{21:31}, i.e. the ratio between the etching speed of the metal of the first superconductor metal layer 21 over the etching speed of the material of the barrier layer, is greater than or equal to 10:1, preferably greater than or equal to 10:1. The etching selectivity S_{21:30b}, i.e. the ratio between the etching speed of the metal of the first superconductor metal layer 21 over the etching speed of the material of the etching stop layer 30b, is greater than or equal to 10:1. The etchings can be with the basis of a chlorinated chemistry. Alternatively, the etching(s) of the superconductor material(s) can be done in fluorinated or fluorocarbon chemistry. In this case, it is preferable to avoid SiN and SiO₂ as a dielectric material for the barrier layer and for the etching stop layer.

A device comprising interconnections (212, 222) and Josephson junctions (211, 223, 31, 221) integrated in the interconnecting levels is thus advantageously obtained. The Josephson junctions comprise, in this case, a lower part formed by the line 211 and the pad 223, an upper part formed by the via 221, and a barrier layer 31 between the lower and upper parts. The Josephson junctions are, in this case, integrated between the second and third metal levels.

The invention is not limited to the embodiments described above. In particular, it can be considered to structure the barrier layer and/or the etching stop layer indirectly, by forming etching masks of inverted polarity, then by performing a localised deposition of the materials of the barrier layer and/or of the etching stop layer.

1. A method for manufacturing a Josephson junction, the method comprising:
a provision of a substrate comprising at least one first connecting pad and one second connecting pad,
a formation of at least one first superconductor metal layer on exposed faces of the first and second connecting pads,
a formation, on the at least one first superconductor metal layer, of at least one etching stop layer,
a structuration of the at least one etching stop layer, through at least one first mask, so as to expose parts of the at least one first superconductor metal layer and to preserve parts of the at least one etching stop layer in the form of at least one closed pattern surmounting the first connecting pad and at least one open pattern surmounting the second connecting pad, said at least one open pattern comprising at least one via opening, opening onto the at least one first underlying superconductor metal layer,
a formation of at least one second superconductor metal layer on the exposed parts of the at least one first superconductor metal layer and on the at least one closed pattern and the at least one open pattern,
a formation, on the at least one second superconductor metal layer, of at least one second mask defining at least one via level in vertical alignment with the at least one closed pattern and in vertical alignment with the at least one via opening of the at least one open pattern,
an etching of the at least one second superconductor metal layer, said etching being configured to form the vias of the at least one via level by stopping on the patterns of the at least one etching stop layer, and
an etching of the at least one first superconductor metal layer on either side of the at least one closed pattern and of the at least one open pattern, said etching being configured to form lower level lines by stopping on the substrate,
wherein the at least one closed pattern of the at least one etching stop layer comprises a barrier layer with the basis of a Josephson junction material having, with respect to the at least one first superconductor metal layer, a selectivity S_{20a:30a} to the etching, greater than or equal to 10:1, such that the at least one open pattern forms, in a stack with a first via of the at least one via level and a first lower level line, an interconnection, and such that the at least one closed pattern forms, in a stack with a second via of the at least one via level and a second lower level line, the Josephson junction.

2. The method according to the preceding claim 1, wherein the barrier layer is with the basis of a material taken from among: SiO₂, AlOₓ, TiO₂, and MgO.

3. The method according to claim 1, wherein the barrier layer has a thickness e₃₀ₐ of between 1 nm and 5 nm.

4. The method according to claim 1, wherein the via(s) of the at least one via level surmounting the at least one closed pattern have a critical dimension CDᵥᵢₐ₂₂₁, taken along an axis x, less than a dimension CD₁, taken along the axis x, of the at least one closed pattern.

5. The method according to claim 1, wherein the via(s) of the at least one via level surmounting the at least one open pattern have a critical dimension CDᵥᵢₐ₂₂₂, taken along an axis x, greater than or equal to a dimension CDₒₚₑₙ of the at least one via opening taken along the axis x.

6. The method according to claim 1, wherein the at least one first superconductor metal layer and the at least one second superconductor metal layer are with the basis of one same superconductor metal material, for example, ZrN, HIN, W, Nb, NbN, Ta, TaN, Ti, TiN, and Al and their alloys.

7. The method according to claim 1, wherein the etching of the at least one second superconductor metal layer and the etching of the at least one first superconductor metal layer are done by one single and same etching, during one single and same step.

8. The method according to claim 1, wherein the at least one closed pattern comprises a first closed pattern and a second closed pattern, said first and second closed patterns being surmounted respectively by third and fourth vias, said method further comprising, after formation of the assembly of the vias of the at least one via level and of the assembly of the lower level lines, a formation of at least one upper level superconductor metal line connecting the third and fourth vias, so as to form a device comprising several Josephson junctions.

9. The method for manufacturing the Josephson junction according to claim 1, comprising:
the provision of the substrate comprising the at least one first connecting pad and one second connecting pad,
a formation of a first superconductor metal layer on exposed faces of the first and second connecting pads,
a formation, on the first superconductor metal layer, of a barrier layer with the basis of a Josephson junction material having, with respect to the first superconductor metal layer, a selectivity S_{21:30a} to the etching, greater than or equal to 10:1,
a structuration of the barrier layer, through the at least one first mask, so as to expose parts of the first superconductor metal layer and to preserve parts of the barrier layer in the form of at least one closed pattern surmounting the first connecting pad and at least one open pattern surmounting the second connecting pad, said at least one open pattern comprising at least one via opening, opening onto the first underlying superconductor metal layer,
a formation of a second superconductor metal layer on the exposed parts of the first superconductor metal layer and on the at least one closed pattern and the at least one open pattern,
a formation, on the second superconductor metal layer, of a second mask defining a second via level in vertical alignment with the at least one closed pattern and in vertical alignment with the at least one via opening of the at least one open pattern,
an etching of the second superconductor metal layer, said etching being configured to form the vias of the second level by stopping on the barrier layer, and
an etching of the first superconductor metal layer on either side of the at least one closed pattern and of the at least one open pattern, said etching being configured to form first level lines by stopping on the substrate.

10. The method for manufacturing a Josephson junction according to claim 1, comprising:
the provision of the substrate comprising the at least one first connecting pad and one second connecting pad,
a formation of a first superconductor metal layer on exposed faces of the first and second connecting pads,
a formation, on the first superconductor metal layer, of an etching stop layer,
a structuration of the etching stop layer, through at least one first mask, so as to expose parts of the first superconductor metal layer and to preserve parts of the etching stop layer in the form of at least one open pattern surmounting the first and second connecting pads, said at least one open pattern comprising at least one via opening, opening onto the first underlying superconductor metal layer,
a formation of a second superconductor metal layer on the exposed parts of the first superconductor metal layer and on the at least one open pattern,
a formation, on the second superconductor metal layer of a barrier layer with the basis of a Josephson junction material having, with respect to the second superconductor metal layer, a selectivity S_{22:30a} to the etching, greater than or equal to 10:1,
a structuration of the barrier layer, through at least one second mask, so as to expose parts of the second superconductor metal layer and to preserve parts of the barrier layer in the form of at least one closed pattern surmounting the first connecting pad,
a formation of a third superconductor metal layer on the exposed parts of the second superconductor metal layer and on the at least one closed pattern,
a formation, on the third superconductor metal layer, of a third mask defining vias in vertical alignment with the at least one closed pattern and in vertical alignment with the at least one via opening of the at least one open pattern, and
at least one etching of the third, second and first superconductor metal layers, said at least one etching being configured to form the vias by stopping on the barrier layer and on the etching stop layer, and to form first level lines by stopping on the substrate.

11. The method according to the preceding claim 10, wherein the at least one closed pattern has a dimension CD₁, taken along an axis x, less than a dimension CD₂, taken along the axis x, of the at least one underlying open pattern.

12. A quantum device comprising, in a stack along a direction z:
a substrate comprising at least one first connecting pad and one second connecting pad,
an interconnection connecting the second connecting pad, comprising:
at least one first superconductor metal line with the basis of a first superconductor metal,
at least one first metal via with the basis of a second superconductor metal, connected to said at least one metal line, and
a first barrier layer inserted between the at least one first via and the at least one first line, said first barrier layer comprising at least one via opening, such that the at least one first via and the at least one first line are connected through said at least one via opening,
a Josephson junction connecting the first connecting pad, comprising:
at least one second metal line with the basis of the first superconductor metal,
at least one second metal via with the basis of the second superconductor metal, and
a second barrier layer inserted between the at least one second via and the at least one second line, said second barrier layer separating the at least one second via and the at least one second line.

13. The device according to claim 12, wherein the at least one first metal via of the interconnection connecting the second connecting pad has a critical dimension CDᵥᵢₐ₂₂₂, taken along an axis x, greater than or equal to a dimension CDₒₚₑₙ of the at least one via opening taken along the axis x.

14. The device according to claim 12, wherein the at least one second metal via of the Josephson junction a critical dimension CDᵥᵢₐ₂₂₁, taken along the axis x, strictly greater than a dimension CD₃₁, taken along the axis x, of the barrier layer separating the at least one via and the at least one line of the Josephson junction.

15. The device according to claim 12, wherein the first and second metals are with the basis of the same metal taken from among ZrN, HIN, W, Nb, NbN, Ta, TaN, Ti, TiN, and Al and their alloys.

16. The device according to claim 12, wherein the first and second barrier layers have a selectivity to the etching S_{21:32a} or S_{21:31} greater than or equal to 10:1 with respect to the first superconductor metal.

17. The device according to claim 12, wherein the second barrier layer inserted between the at least one second via and the at least one second line of the Josephson junction is continuous and does not comprise any via opening.

18. The device according to claim 12, wherein the first and second barrier layers are distinct and separated from one another.
